(19) United States
(12) Patent Application Publication
(10) Pub. No.: US 2023/0229079 A1
(43) Pub. Date: Jul. 20, 2023

(54) PHOTOSENSITIVE RESIN COMPOSITION, CURED PRODUCT THEREOF, AND WIRING STRUCTURE CONTAINING CURED PRODUCT

(71) Applicant: NAMICS CORPORATION, Niigata (JP)

(72) Inventors: Pawel CZUBAROW, Framingham, MA (US); Masayoshi OTOMO, Niigata (JP); Irma Yolanda KAPOGLIS, Byfield, MA (US); Nicholas Charles KRASCO, Byfield, MA (US); Frank Anthony LETIZIA, III, Byfield, MA (US); Toshiyuki SATO, Niigata (JP)

(21) Appl. No.: 18/009,628

(22) PCT Filed: Jun. 7, 2021
(86) PCT No.: PCT/JP2021/021563

§ 371 Date: Dec. 9, 2022

Related U.S. Application Data
(60) Provisional application No. 63/046,808, filed on Jul. 1, 2020.

(51) Int. Cl. G03F 7/033; C08K 5/3417; C08L 83/06; G03F 7/075; C08F 290/06

(52) U.S. Cl. CPC G03F 7/033; C08K 5/3417; C08L 83/06; G03F 7/0757; C08F 290/062; C08L 2203/16; C08L 2203/206

(57) ABSTRACT

There are provided a photosensitive resin composition, a cured product thereof, and a wiring structure body, an electronic component, a semiconductor device, and a camera module each including the cured product. This photosensitive resin composition is cured by irradiation with active energy rays, instead of by heat treatment at high temperatures. In this photosensitive resin composition, film loss after a development process is restrained. Furthermore, a miniaturized pattern can be accurately formed by photolithography. An aspect of the present invention is a photosensitive resin composition including components (A) to (C): (A) a modified polyphenylene ether represented by formula (1) and formula (2), (B) a silsesquioxane compound represented by formula (3), and (C) a photopolymerization initiator, a cured product thereof, and a wiring structure body, an electronic component, a semiconductor device, and a camera module each including the cured product.

### TECHNICAL FIELD

An aspect of the present disclosure relates to a photosensitive resin composition, a cured product thereof, and a wiring structure body, an electronic component, a semiconductor device, and a camera module each including the cured product.

### BACKGROUND ART

Wiring in a wiring structure body constituting an electronic component such as an integrating circuit is significantly miniaturized. An interval between external terminals, which connect a semiconductor chip contained in a wiring structure body with exterior wiring, is also extremely narrowed. It is difficult to narrow the interval between external terminals to not more than a certain level. Therefore, a rewiring layer such as copper is disposed on a surface of a semiconductor chip, and external terminals such as bumps are disposed on the rewiring layer. Accordingly, a specific interval between external terminals is maintained. An insulating film including an insulating material is formed between the surface of the semiconductor chip and the rewiring layer and between the rewiring layer and a UBM (Under Bunp Metallurgy) layer on which bumps are disposed. As a method for forming the insulating layer on which the rewiring layer is to be disposed, a method of performing patterning by photolithography is adopted. As the insulating material for forming the insulating layer of the wiring structure body, a photosensitive resin composition is used.

For example, PATENT LITERATURE 1 discloses a photosensitive resin composition for photo spacers which includes a polymerizable compound, a binder, and a photopolymerization initiator. The polymerizable compound has a group having a bridged ring structure and a group having an ethylene-based unsaturated bond. PATENT LITERATURE 2 discloses a coating composition disposed on an optical fiber or an optical planer waveguide. This coating composition includes a silsesquioxane component, and the silsesquioxane component has one or more reactive functional groups which are curable by UV irradiation. PATENT LITERATURE 3 discloses a multi-layered body including a rewiring layer containing copper, an insulating layer containing polyimide or polybenzoxazole, and a copper oxide layer. PATENT LITERATURE 4 discloses a photosensitive resin material. This photosensitive resin material includes, for improving adhesive properties with rewiring metal, an alkali-soluble resin, a photosensitizer, and a carboximide compound containing a molecular structure having a dicarboximide structure.

### CITATION LIST

### Patent Literature

PATENT LITERATURE 1: JP-A-2009-128487
PATENT LITERATURE 2: JP-T-2017-534693
PATENT LITERATURE 3: JP-A-2017-92152
PATENT LITERATURE 4: JP-A-2017-111383

### SUMMARY OF THE INVENTION

### Problems to be Solved by Invention

However, the photosensitive resin composition and others disclosed in PATENT LITERATURES 1 to 4 are all not cured only by active energy rays (for example, UV rays). For curing the photosensitive resin composition and others, heat treatment at temperatures of about 150° C. to 300° C. needs to be performed. However, when the heat treatment is performed after patterning by photolithography, the formed pattern is deformed because of shrinkage due to heat. This makes it difficult to form a desired miniaturized and accurate pattern. Regarding the wiring of the rewiring layer which is being miniaturized, the line and space (hereinafter, also described as “L/S”) is required to be 2 μm/2 μm or less. In reducing the L/S, deformation of a pattern, caused by heat treatment, is seriously problematic. A material used in the wiring structure body is required to not only restrain the deformation of a pattern but also restrain the film loss in a development process after patterning. Also, in an electronic component, the speed of transmission signals is required to be increased, and the frequency of transmission signals is also being significantly increased. Therefore, a material used in a wiring structure body of an electronic component is also required to have excellent electrical characteristics (low dielectric constant (e) and low dielectric loss tangent (tan δ)) in a high frequency range, specifically, in a frequency range from 1 GHz to 10 GHz.

Therefore, an object of the present disclosure is to provide a photosensitive resin composition, a cured product thereof, and a wiring structure body, an electronic component, a semiconductor device, and a camera module each including the cured product, as described below. This photosensitive resin composition is cured by irradiation with active energy rays, instead of by heat treatment at high temperatures of, for example, 150° C. or higher. This photosensitive resin composition also has restrained film loss after a development process. Furthermore, a miniaturized pattern can be accurately formed by photolithography.

### Solutions to Problems

Solutions to the above-described problems are as described below. The present disclosure encompasses the following aspects.

[1] A photosensitive resin composition comprising components (A) to (C) below:

(A) a modified polyphenylene ether resin represented by formula (1) below

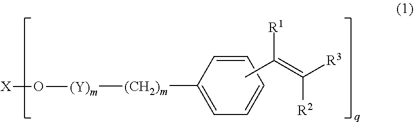

[wherein R¹ to R³ each independently represent a hydrogen atom, an alkyl group, an alkenyl group, or an alkynyl group,

X represents a q-valent unsubstituted or substituted aromatic hydrocarbon group,

Y represents an unsubstituted or substituted phenol repeating unit represented by formula (2) below

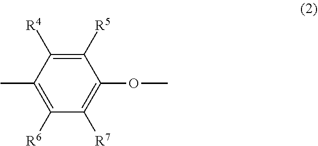

[wherein R⁴ to R⁷ each independently represent a hydrogen atom, an alkyl group, an alkenyl group, an alkynyl group, or an alkenylcarbonyl group],

m represents an integer of 1 to 100,

n represents an integer of 1 to 6, and

q represents an integer of 1 to 4];

(B) a compound represented by formula (3) below

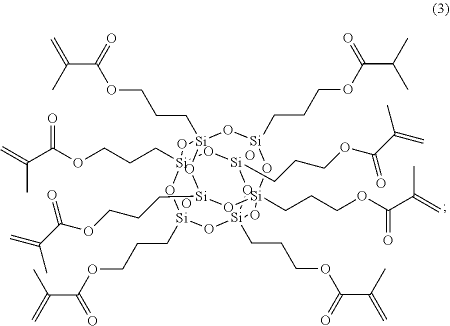 [SMILES: C=C(C)C(=O)OCCC[Si]12O[Si]3(CCCOC(=O)C(=C)C)O[Si]4(CCCOC(=O)C(=C)C)O[Si](CCCOC(=O)C(=C)C)(O1)O[Si]1(CCCOC(=O)C(=C)C)O[Si](CCCOC(=O)C(=C)C)(O2)O[Si](CCCOC(=O)C(=C)C)(O3)O[Si](CCCOC(=O)C(C)C)(O4)O1]

and

(C) a photopolymerization initiator.

[2] The photosensitive resin composition according to [1], further comprising

(D) a bifunctional acrylic resin represented by formula (4) below

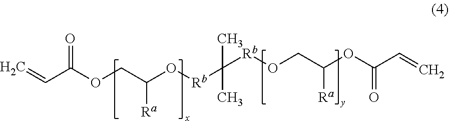

[wherein each R^{a} independently represents a hydrogen atom or a methyl group,

each R^{b} independently represents a divalent hydrocarbon group, and

x and y each independently represent an integer of 1 to 5].

[3] The photosensitive resin composition according to [1] or [2], wherein the component (C) is at least one selected from the group consisting of an acylphosphine oxide-based photopolymerization initiator, an oxime ester-based photopolymerization initiator, and an alkylphenone-based photopolymerization initiator.
[4] The photosensitive resin composition according to any one of [1] to [3], wherein a mass ratio of the component (A) relative to a total amount of the component (A) and the component (B) is 0.10 to 0.99.
[5] The photosensitive resin composition according to any one of [1] to [4], wherein a content of the component (C), relative to 100% by mass of the photosensitive resin composition, is 1.0 to 20.0% by mass.
[6] The photosensitive resin composition according to any one of [2] to [5], wherein a mass ratio of the component (D) relative to a total amount of the component (B) and the component (D) is 0.01 to 0.99.
[7] The photosensitive resin composition according to any one of [1] to [6], further comprising (E) a crystallizable or amorphous thermoplastic resin (excluding the bifunctional acrylic resin).
[8] The photosensitive resin composition according to [7], wherein the component (E) is at least one selected from the group consisting of a liquid crystal polymer, polyethylene, polypropylene, polyacetal, polyethylene terephthalate, polybutylene terephthalate, polyphenylene sulfide, polyether ketone, polytetrafluoroethylene, polyvinyl chloride, polystyrene, polymethyl methacrylate, acrylonitrile-butadiene-styrene, polycarbonate, polyether sulfone, polyether imide, and polyamide imide.
[9] The photosensitive resin composition according to any one of [1] to [8], which is used for forming a wiring structure body containing a rewiring layer.
[10] A cured product obtained by curing the photosensitive resin composition according to any one of [1] to [9].
[11] A wiring structure body comprising the cured product according to [10].
[12] An electronic component comprising the cured product according to [10].
[13] A semiconductor device comprising the cured product according to [10].
[14] A camera module comprising the cured product according to [10].

### Effects of Invention

According to the above-described aspects of the present disclosure, there can be provided a photosensitive resin composition, a cured product obtained by curing the photosensitive resin composition, and a wiring structure body, an electronic component, a semiconductor device, and a camera module each including the cured product, as described below. This photosensitive resin composition is cured by irradiation with active energy rays, instead of by heat treatment at high temperatures of, for example, 150° C. or higher. This photosensitive resin composition also has restrained film loss after development by photolithography. Furthermore, a miniaturized pattern can be accurately formed.

### BRIEF DESCRIPTION OF THE DRAWINGS

FIG. 1 is an enlarged view illustrating an example of a three-line pattern having an US of 2 μm/2 μm.

FIG. 2 is a graph illustrating contrast curves indicating a relationship of a film thickness ratio to an irradiation amount for cured products obtained with the photosensitive resin compositions of Examples 6, 7, and 12, and an ideal contrast curve.

FIG. 3 is a graph illustrating a contrast curve indicating a relationship of a film thickness ratio to an irradiation amount for cured products obtained with the photosensitive resin composition according to Comparative Example 1, and an ideal contrast curve.

### DESCRIPTION OF EMBODIMENTS

Hereinafter, a photosensitive resin composition, a cured product obtained by curing the photosensitive resin composition, and a wiring structure body, an electronic component, a semiconductor device, and a camera module each including the cured product according to an aspect of the present disclosure will be described based on embodiments. However, the below-described embodiments are examples for embodying the technological idea of the present disclosure. The technical idea of the present disclosure is not limited to a photosensitive resin composition, a cured product obtained by curing the photosensitive resin composition, and a wiring structure body, an electronic component, a semiconductor device, and a camera module each including the cured product described below.

A photosensitive resin composition according to a first embodiment of the present disclosure includes: (A) a certain modified polyphenylene ether represented by formulae (1) and (2) (hereinafter, sometimes described as “component (A)”); (B) a compound represented by formula (3) (hereinafter, sometimes described as “component (B)”; and (C) a photopolymerization initiator (hereinafter, sometimes described as “component (C)”). The photosensitive resin composition includes the modified polyphenylene ether of component (A). Therefore, the dielectric constant (s) of the photosensitive resin composition is 3.0 or less, and the dielectric loss tangent (tan δ) is 0.01 or less. The photosensitive resin composition has such a low dielectric constant and a low dielectric loss tangent. Therefore, the use of the photosensitive resin composition can provide a cured product having good electrical properties when used in a high frequency range. The photosensitive resin composition does not need to be heat-treated at high temperatures of, for example, 150° C. or higher, for obtaining a cured product. Therefore, a cured product obtained by curing the photosensitive resin composition is unlikely to be deformed by shrinkage caused by heat treatment at high temperatures of 150° C. or higher. The photosensitive resin composition includes the compound of component (B). Therefore, the reaction of the photosensitive resin composition in response to irradiation with active energy rays (for example, UV rays) is unlikely to proceed when the irradiation amount is not more than a certain amount. With the irradiation amount exceeding a certain amount, the reaction rapidly proceeds, the photosensitive resin composition is sufficiently cured, and a cured product having restrained film loss after development is obtained.

A contrast curve for the photosensitive resin composition is obtained by plotting a film thickness ratio relative to an irradiation amount of active energy rays. The film thickness ratio is a ratio of the film thickness of the cured product after development relative to the coating film thickness of the photosensitive resin composition. The photosensitive resin composition includes component (A), component (B), and component (C). Therefore, in this photosensitive resin composition, the reaction of the photosensitive resin composition is unlikely to proceed when the irradiation amount is not more than a certain amount and rapidly proceeds when the irradiation amount exceeds a certain amount. Accordingly, this photosensitive resin composition exhibits a contrast curve that is closer to an ideal contrast curve as described below. That is, in the contrast curve of this photosensitive resin composition, the film thickness ratio sharply rises at the start and thereafter becomes constant even when the irradiation amount increases. Since the photosensitive resin composition includes component (A), component (B), and component (C), it exhibits a contrast curve that is closer to the ideal contrast curve. Therefore, with this photosensitive resin composition, a miniaturized and accurate pattern having an US of 2 μm/2 μm or less can be formed by photolithography.

### Component (A): Modified Polyphenylene Ether

The photosensitive resin composition includes (A) a modified polyphenylene ether (PPE) resin represented by formula (1) below. This PPE resin is sometimes described as component (A) or the PPE resin of component (A).

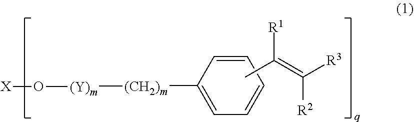

[In the formula,

R¹ to R; each independently represent a hydrogen atom, an alkyl group, an alkenyl group, or an alkynyl group,

X represents a q-valent unsubstituted or substituted aromatic hydrocarbon group,

Y represents an unsubstituted or substituted phenol repeating unit represented by formula (2) below:

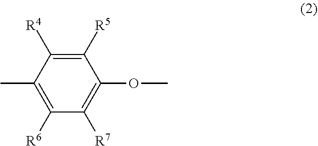

[wherein R⁴ to R⁷ each independently represent a hydrogen atom, an alkyl group, an alkenyl group, an alkynyl group, or an alkenylcarbonyl group],

m represents an integer of 1 to 100,

n represents an integer of 1 to 6, and

q represents an integer of 1 to 4.]

In general, an x-valent (x represents an integer of 1 or more) hydrocarbon group indicates an x-valent group obtained by removing x hydrogen atoms from a carbon atom of hydrocarbon. Therefore, the above-described q-valent unsubstituted or substituted aromatic hydrocarbon group indicates a 1 to 4-valent group obtained by removing 1 to 4 hydrogen atoms from a carbon atom of aromatic hydrocarbon which may or may not be substituted.

The term “alkyl group” denotes a monovalent saturated hydrocarbon group. In the present embodiment, the alkyl group is preferably a C₁-C₁₀ alkyl group, more preferably a C₁-C₆ alkyl group, further preferably a C₁-C₄ alkyl group, particularly preferably a C₁-C₂ alkyl group. Examples of such an alkyl group include a methyl group, an ethyl group, a propyl group, an isopropyl group, a butyl group, an isobutyl group, a sec-butyl group, a tert-butyl group, a pentyl group, and a hexyl group.

The term “alkenyl group” denotes a monovalent unsaturated hydrocarbon group having at least one carbon-carbon double bond. In the present embodiment, the alkenyl group is preferably a C₂-C₁₀ alkenyl group, more preferably a C₂-C₆ alkenyl group, and further preferably a C₂-C₄ alkenyl group. Examples of such an alkenyl group include an ethenyl group (vinyl group), a 1-propenyl group, a 2-propenyl group, a 1-butenyl group, a 2-butenyl group, an isobutenyl group, a 1-pentenyl group, and a 1-hexenyl group. —CR¹═CR²R³, which is a group in formula (1) above, is also an alkenyl group.

The term “alkynyl group” denotes a monovalent unsaturated hydrocarbon group having at least one carbon-carbon triple bond. In the present embodiment, the alkynyl group is preferably a C₂-C₁₀ alkynyl group, more preferably a C₂-C₆ alkynyl group, and further preferably a C₂-C₄ alkynyl group. Examples of such an alkynyl group include an ethynyl group, a 1-propynyl group, a 2-propynyl group, a butynyl group, an isobutynyl group, a pentynyl group, and a hexynyl group.

The term “alkenylcarbonyl group” denotes a carbonyl group substituted with the above-described alkenyl group. Examples thereof include an acryloyl group and a methacryloyl group.

A moiety represented by —(Y)ₘ— in component (A) corresponds to the main chain of the PPE resin. Preferably, R⁴ and R⁶ in the previously-described unsubstituted or substituted phenol repeating unit Y represent a hydrogen atom, and R⁵ and R⁷ represents a methyl group. One terminal of the moieties represented by —(Y)ₘ— is bonded to the aromatic hydrocarbon group X via an oxygen atom. The other terminal is bonded, via n methylene groups, to a phenyl group substituted with —CR¹═CR²R³ which is the alkenyl group. The —CR¹═CR²R³ as the alkenyl group may be located at any of the ortho position, the meth position, and the para position to the methylene group. In an aspect, n in formula (1) is an integer of 1 to 4. In an aspect, n in formula (1) is 1 or 2. In an aspect, n in formula (1) is 1. In another aspect, R¹ to R³ in formula (1) are all a hydrogen atom.

Also, the number m of repeating units Y's in formula (1) is preferably 1 to 80, more preferably 1 to 30, and further preferably 1 to 5.

In component (A), the aromatic hydrocarbon group X of formula (1) is bonded with q moieties represented by —(Y)ₘ— via respective oxygen atoms. q is preferably 2 or 3 and more preferably 2. Also, X preferably has a structure represented by the formula below.

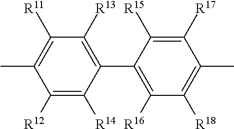

[In the formula, R¹¹ to R¹⁸ each independently represent a hydrogen atom or a C₁-C₆ alkyl group.]

X more preferably has a structure represented by the formula below.

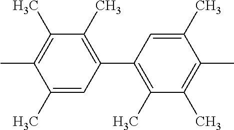

From the viewpoint of fluidity during molding of the photosensitive resin composition, dielectric properties and heat resistance of a cured product obtained by curing the photosensitive resin composition, compatibility of other components contained in the photosensitive resin composition, and others, the number average molecular weight of component (A) is preferably 500 or more and 5000 or less. When the number average molecular weight of component (A) is excessively low, toughness of a cured product obtained by curing the photosensitive resin composition sometimes deteriorates. On the other hand, when the number average molecular weight of component (A) is excessively high, compatibility of component (A) with other components (for example, an optionally added solvent) sometimes deteriorates. For example, it sometimes becomes difficult to add a solvent to the photosensitive resin composition such that the viscosity is suitable for spin coating. The number average molecular weight of component (A) is more preferably 750 or more and 3000 or less and further preferably 1000 or more and 2500 or less. The number average molecular weight of component (A) can be measured by, for example, gel permeation chromatography.

The content of component (A) in the photosensitive resin composition, relative to 100% by mass of the photosensitive resin composition, is preferably 30.0 to 98.0% by mass, more preferably 35.0 to 97.0% by mass, further preferably 40.0 to 96.0% by mass, and particularly preferably 45.0 to 95.0% by mass. When the content of component (A) in 100% by mass of the photosensitive resin composition is 30.0 to 98.0% by mass, there can be obtained a cured product having a low dielectric constant and a low dielectric loss tangent, that is, a cured product having good electrical properties suitable for use in a high frequency range.

As component (A), a commercially available product can be used. An example of a usable commercially available product of component (A) is OPE 2St 1200 (manufactured by Mitsubishi Gas Chemical Company Inc.). Component (A) can be prepared by a known method. For example, component (A) can be prepared by the following method. In this method, there are used an appropriate q-valent phenol (such as 2,2′,3,3′,5,5′-hexamethylbiphenyl-4,4′-diol) having a structure represented by X—(OH)_{q} (wherein X and q have the same meaning as above) and an appropriate monovalent phenol (such as 2,6-dimethylphenol) having a structure represented by the formula below.

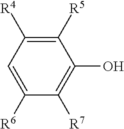

[In the formula, R⁴ to R⁷ each have the same meaning as above.]

This method includes oxidizing and copolymerizing these phenols by a known method thereby to prepare a polyphenylene ether resin having a hydroxyl group at the terminal. Furthermore, this method includes modifying the obtained resin by reaction with an appropriate modifier (for example, chloromethylstyrene).

### Component (B): Silsesquioxane Compound

The photosensitive resin composition includes (B) a compound represented by the formula (3) below.

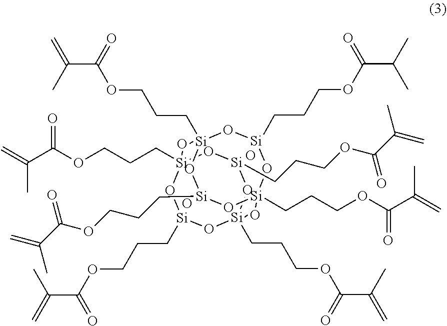 [SMILES: C=C(C)C(=O)OCCC[Si]12O[Si]3(CCCOC(=O)C(=C)C)O[Si]4(CCCOC(=O)C(=C)C)O[Si](CCCOC(=O)C(=C)C)(O1)O[Si]1(CCCOC(=O)C(=C)C)O[Si](CCCOC(=O)C(=C)C)(O2)O[Si](CCCOC(=O)C(=C)C)(O3)O[Si](CCCOC(=O)C(C)C)(O4)O1]

The compound represented by formula (3) is a compound having a cage-type silsesquioxane structure with eight (meth)acryloylalkyl groups, specifically, acryloyloxypropoxy groups. The compound represented by formula (3) of component (B) is sometimes described as a silsesquioxane compound of component (B). The molecular weight of the silsesquioxane compound of component (B) is preferably 2000 or less and more preferably 1000 to 2000.

In the photosensitive resin composition, the mass ratio (A/A+B) of component (A) relative to the total amount of component (A) and component (B) is preferably 0.10 to 0.99, more preferably 0.20 to 0.98, further preferably 0.30 to 0.97, still further preferably 0.40 to 0.96, and particularly preferably 0.50 to 0.96. When the mass ratio (A/A+B) of component (A) relative to the total amount of component (A) and component (B), in the photosensitive resin composition, is in a range of 0.10 to 0.99, a cured product having restrained film loss after development is obtained by irradiation of the photosensitive resin composition with active energy rays (for example, UV rays). Also, with the photosensitive resin composition, a miniaturized and accurate pattern having an L/S of 2 μm/2 μm or less can be formed by photolithography.

When the photosensitive resin composition includes a bifunctional acrylic resin as component (D) described later, the mass ratio (A/A+B+D) of component (A) relative to the total amount of component (A), component (B), and component (D) is also preferably 0.10 to 0.99, more preferably 0.20 to 0.98, further preferably 0.30 to 0.97, still further preferably 0.40 to 0.96, and particularly preferably 0.50 to 0.96. When the mass ratio of component (A) relative to the total amount of component (A), component (B), and component (D) is in the previously-described range, the photosensitive resin composition has good film formation properties. Therefore, a cured product having restrained film loss after development is obtained by irradiation with active energy rays.

The content of component (B) in the photosensitive resin composition, relative to 100% by mass of the photosensitive resin composition, is preferably 1.0 to 60.0% by mass, more preferably 2.0 to 58.0% by mass, further preferably 3.0 to 55.0% by mass, and particularly preferably 4.0 to 50.0% by mass. When the content of component (B) in 100% by mass of the photosensitive resin composition is 1.0 to 60.0% by mass, heat treatment at high temperatures of, for example, 150° C. or higher is not required, and a cured product having restrained film loss after development is obtained by irradiation of the photosensitive resin composition with active energy rays (for example, UV rays). Also, with the photosensitive resin composition, a miniaturized and accurate pattern having an L/S of 2 μm/2 μm or less can be formed by photolithography.

As component (B), a commercially available product can be used. An example of the commercially available product of component (B) is POSS (Polyhedral Oligomeric Silsesquioxane) series manufactured by Hybrid Inc. Specifically, Acrylo POSS Cage Mixture MA0736 (manufactured by Hybrid Plastic Inc.) can be used.

### Component (C): Photopolymerization Initiator

The photosensitive resin composition includes (C) a photopolymerization initiator. Component (C) is not particularly limited as long as it is a compound that generates, in response to irradiation with active energy rays, radicals which cause reaction of component (A), component (B), and, as necessary, component (D). Here, active energy rays include all lights in a broad sense, for example, radiations such as a rays and p rays, electromagnetic waves such as γ rays and X rays, electron beams (EB), and visible rays of about 100 to 400 nm, and preferably UV rays. As component (C), one photopolymerization initiator may be used, or two or more photopolymerization initiators may be used in combination.

Component (C) to be used is preferably at least one selected from the group consisting of an oxime ester-based polymerization initiator, an acylphosphine oxide-based polymerization initiator, and an alkylphenone-based polymerization initiator, in order to promote the reaction of component (A), component (B), and, as necessary, component (D) by irradiation with active energy rays.

Examples of the oxime ester-based polymerization initiator include 1-[9-ethyl-6-(2-methylbenzoyl)-9H-carbazole-3-yl]-ethanone-,1-(0-acetyloxime) and 1,2-octadione, 1-[4-(phenylthio)phenyl]-,2-(o-benzoyloxime).

Examples of the acyl phosphine oxide-based polymerization initiator include bis(2,4,6-trimethylbenzoyl)-phenyl-phosphine oxide and 2,4,6-trimethylbenzoyl-diphenyl-phosphine oxide.

An example of the alkylphenone-based polymerization initiator is 2-benzyl-2-(dimethylamino)-4′-morpholinobutyrophenone.

The content of component (C) in the photosensitive resin composition, relative to 100% by mass of the photosensitive resin composition, is preferably 1.0 to 20.0% by mass, more preferably 3.0 to 18.0% by mass, and further preferably 5.0 to 15.0% by mass. When the content of component (C) in 100% by mass of the photosensitive resin composition is 1.0 to 20.0% by mass, heat treatment at high temperatures of, for example, 150° C. or higher is not required, and a cured product can be obtained by irradiation of the photosensitive resin composition with active energy rays (for example, UV rays).

As component (C), a commercially available product can be used. Examples of a usable commercially available product of component (C) include Irgacure OXE-01 (manufactured by BASF), Irgacure OXE-02 (manufactured by BASF), Omnirad 819 (former Irgacure 819) (manufactured by IGM Resins B.V.), and Omnird 369 (former Irgacure 369) (manufactured by IGM Resins B.V).

### Component (D): Bifunctional Acrylic Resin

The photosensitive resin composition preferably further includes (D) a bifunctional acrylic resin represented by formula (4) below.

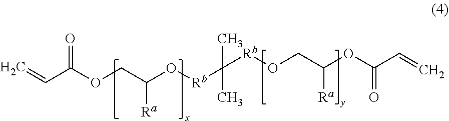

[In the formula, each R^{a} independently represents a hydrogen atom or a methyl group,

each R^{b} independently represents a divalent hydrocarbon group, and

x and y each independently represent an integer of 1 to 5.]

This bifunctional acrylic resin is sometimes described as component (D) or the bifunctional acrylic resin of component (D).

R^{b}'s in formula (4) are each independently preferably a methylene group or a p-phenylene group. In formula (4), R^{b} may be a methylene group, and R^{a} may be a methyl group. In formula (4), R^{b} may be a phenylene group, and R may be a hydrogen atom.

When the photosensitive resin composition includes the bifunctional acrylic resin of component (D), the reaction of the photosensitive resin composition in response to irradiation with active energy rays (for example, UV rays) is unlikely to proceed with the irradiation amount of not more than a certain amount. With the irradiation amount exceeding a certain amount, the reaction rapidly proceeds, and component (D), together with component (B), sufficiently reacts with component (A) to obtain a cured product of which film loss after development is restrained. When component (D) is bifunctional, that is, when component (D) has two acryloyl groups, unreacted component (A) reacts with component (D) after component (A) and component (B) rapidly reacted, even when, for example, component (A) has a low molecular weight. Therefore, there can be obtained a cured product which has good pattern molding properties by photolithography and further has restrained film loss after development. When the photosensitive resin composition includes component (D), component (A) having a low molecular weight can be used. Therefore, the film formation properties of the photosensitive resin composition can be improved. Accordingly, a film of the photosensitive resin composition can be formed by a relatively simple method such as spin coating. In a monofunctional acrylic resin having one acryloyl group in one molecule, a reaction between unreacted component (A) and the monofunctional acrylic resin does not proceed after component (A) and component (B) had reacted, leading to the occurrence of film loss after development in some cases. In a multifunctional acrylic resin having three or more acryloyl groups in one molecule, a reaction between unreacted component (A) and the multifunctional acrylic resin having three or more acryloyl groups in one molecule also does not proceed after component (A) and component (B) reacted, because of an excessive number of functional groups, which sometimes leads to the occurrence of film loss after development.

Examples of component (D) include ethoxylated bisphenol A diacrylate (diacrylate of bisphenol A bonded with (poly)ethylene glycol), propoxylated bisphenol A diacrylate (diacrylate of bisphenol A bonded with (poly)propylene glycol), ethoxylated neopentyl glycol diacrylate (diacrylate of neopentyl glycol bonded with (poly)ethylene glycol), and propoxylated neopentyl glycol diacrylate (diacrylate of neopentyl glycol bonded with (poly)propylene glycol). As the bifunctional acrylic resin of the component (D), one resin may be used, or two or more resins may be used in combination.

In the photosensitive resin composition, the mass ratio (D/B+D) of component (D) relative to the total amount of component (B) and component (D) is preferably 0.01 to 0.99, more preferably 0.02 to 0.80, further preferably 0.03 to 0.70, and still further preferably 0.04 to 0.60. When the photosensitive resin composition includes component (D), and the mass ratio (D/B+D) of component (D) relative to the total amount of component (B) and component (D) is in a range of 0.01 to 0.99, the photosensitive resin composition has good film formation properties. Therefore, a cured product having restrained film loss after development is obtained by irradiation of the photosensitive resin composition with active energy rays (for example, UV rays).

The content of component (D) in the photosensitive resin composition, relative to 100% by mass of the photosensitive resin composition, is preferably 59.0% by mass or less, more preferably 1.0 to 57.0% by mass, further preferably 3.0 to 55.0% by mass, and still further preferably 5.0 to 50.0% by mass. When the photosensitive resin composition includes component (D), and the content of component (D) in 100% by mass of the photosensitive resin composition is 59.0% by mass, the photosensitive resin composition has good film formation properties. Therefore, a cured product having restrained film loss after development is obtained by irradiation of the photosensitive resin composition with active energy rays (for example, UV rays).

As component (D), a commercially available product can be used. Examples of a usable commercially available product of component (D) include ethoxylated (4) bisphenol A diacrylate SR601 (manufactured by Sartomer Chemical Co.) and propoxylated (2) neopentyl glycol diacrylate SR9003B (manufactured by Sartomer Chemical Co.). Component (D) can be prepared by a known method. For example, component (D) can be prepared by a method including bringing an appropriate diol compound having a structure represented by (CH₃)₂(CR^{b}OH)₂ (wherein R^{b} has the same meaning as above) into reaction with acrylic acid or its derivative.

### Component (E): Crystallizable or Amorphous Thermoplastic Resin

The photosensitive resin composition may further include component (E) a crystallizable or amorphous thermoplastic resin (excluding the bifunctional acrylic resin). This thermoplastic resin is sometimes described as component (E) or the thermoplastic resin of component (E). When the photosensitive resin composition includes the thermoplastic resin of component (E), for example, temperature properties of the photosensitive resin composition can be improved, and molding properties and others of the photosensitive resin composition can also be improved.

Examples of the crystallizable thermoplastic resin of component (E) include at least one selected from the group consisting of a liquid crystal polymer, polyethylene, polypropylene, polyacetal, polyethylene terephthalate, polybutylene terephthalate, polyphenylene sulfide, polyether ketone, and polytetrafluoroethylene. Examples of the amorphous thermoplastic resin of component (E) include at least one selected from the group consisting of polyvinyl chloride, polystyrene, polymethyl methacrylate, acrylonitrile-butadiene-styrene, polycarbonate, polyether sulfone, polyether imide, and polyamide imide. As the thermoplastic resin of components (E), one resin may be used, or two or more resins may be used in combination.

The content of component (E) in the photosensitive resin composition, relative to 100% by mass of the photosensitive resin composition, is preferably 40.0% by mass or less, preferably 1.0 to 35.0% by mass, more preferably 2.0 to 30.0% by mass, further preferably 3.0 to 25.0% by mass, and still further preferably 5.0 to 20.0% by mass. When the content of component (E) in 100% by mass of the photosensitive resin composition is 40.0% by mass or less, a cured product having restrained film loss after development is obtained by irradiation of the photosensitive resin composition with active energy rays (for example, UV rays). Furthermore, the photosensitive resin composition can have good other properties such as temperature properties and molding properties.

### Component (F): Coupling Agent

The photosensitive resin composition may include a coupling agent. The coupling agent is a component having two or more different functional groups in one molecule. One of the functional groups is a functional group to be chemically bonded with an inorganic material, and another is a functional group to be chemically bonded with an organic material. When the coupling agent is included in the photosensitive resin composition, adhesive properties between the photosensitive resin composition and other materials can be enhanced. As described herein, the coupling agent is sometimes described as component (F) or the coupling agent of component (F).

Examples of the coupling agent of component (F) include at least one selected from the group consisting of a silane coupling agent, an aluminum coupling agent, and a titanium coupling agent. As the coupling agent of component (F), one coupling agent may be used, or two or more coupling agents may be used in combination.

Component (F) is preferably a silane coupling agent. Examples of a functional group contained in the silane coupling agent include an alkoxy group, a vinyl group, an epoxy group, a styryl group, a methacryl group, an acryl group, an amino group, an isocyanurate group, a ureide group, a mercapto group, a sulfide group, and an isocyanate group.

The content of component (F) in the photosensitive resin composition, relative to 100% by mass of the photosensitive resin composition, is preferably 30.0% by mass or less, more preferably 0.10 to 30.0% by mass, further preferably 0.20 to 20.0% by mass, still further preferably 0.50 to 10.0% by mass, and particularly preferably 0.80 to 3.0% by mass or less. When the photosensitive resin composition includes component (F), and the content of component (F) in 100% by mass of the photosensitive resin composition is 30.0% by mass or less, the photosensitive resin composition has good adhesive properties with other materials. An example of other materials is a substrate.

As component (F), a commercially available product can be used. Examples of a usable commercially available product of component (F) include 3-methacryloxypropyltrimethoxysilane KBM 503 and vinyltrimethoxysilane KBM 1003 (manufactured by Shin-Etsu Silicone Co., Ltd.), and Coatsil MP200 Silane (manufactured by Momentive-Performance Materials Japan LLC).

The photosensitive resin composition may be added with a filming agent in order to impart flexibility. For example, when the photosensitive resin composition is used to form an insulating layer of a wiring structure body, and a filming agent is added so that flexibility is imparted to the photosensitive resin composition, film formation is facilitated, and a film can be easily formed. Examples of the filming agent include at least one selected from the group consisting of phenoxy resin and acrylic resin (excluding the bifunctional acrylic resin represented by formula (4)). An example of the phenoxy resin is polyhydroxy polyether. This polyhydroxy polyether is synthesized by direct reaction between a divalent phenol compound and epichlorhydrin or by addition polymerization reaction between a divalent phenol compound and diglycidyl ether. The acrylic resin (excluding the bifunctional acrylic resin represented by formula (4)) refers to a homopolymer or a copolymer of acrylic acid and/or methacrylic acid, or their derivatives (for example, ester and amide). As the filming agent, a commercially available product may be used. Examples of the commercially available product of the filming agent include bisphenol A-type phenoxy resin 4250 (manufactured by Mitsubishi Chemical Corporation), bisphenol A-type phenoxy resin Fx316 (manufactured by Nippon Steel Chemical & Material Co., Ltd.), bisphenol A-type phenoxy resin YP50 (manufactured by Nippon Steel Chemical & Material Co., Ltd.), and polymethyl methacrylate-butylacrylamide-triblock copolymer Nanostrength (registered trademark) M52N (manufactured by ARKEMA).

The photosensitive resin composition may further include, as necessary, at least one additive agent selected from the group consisting of an ion trapping agent, a levelling agent, an antioxidant, and a thixotropy-imparting agent. Also, the photosensitive resin composition may include a viscosity adjuster, a flame retardant, a solvent, or others.

### Production Method of Photosensitive Resin Composition

The photosensitive resin composition can be produced by mixing component (A), component (B), and component (C). The photosensitive resin composition can be produced by mixing, as necessary, at least one component selected from the group consisting of component (D), component (E), and component (F), together with component (A), component (B), and component (C). The production method of the photosensitive resin composition is not particularly limited. The photosensitive resin composition can be produced by mixing raw materials of the components using a mixing device such as a grinder, a pot mill, a triple roll mill, a hybrid mixer, a rotary mixer, or a twin-shaft mixer. These components may be mixed simultaneously. Alternatively, a part of these components may be previously mixed, and the remainder may be thereafter mixed. Also, the previously-described devices may be appropriately used in combination to produce the photosensitive resin composition.

### Cured Product

The photosensitive resin composition is irradiated with active energy rays to obtain a cured product. A uniform thin film of the photosensitive resin composition can be formed by a relatively simple film formation method such as spin coating. The thin film formed with the photosensitive resin composition is patterned by photolithography to form a miniaturized and accurate pattern. The photosensitive resin composition can be sufficiently cured by irradiation with active energy rays. The patterned thin film does not need to be treated at high temperatures (for example, 150° C. or higher). This can prevent the formed wiring pattern from deforming because of, for example, shrinkage caused during treatment at high temperatures.

The cured product obtained by curing the photosensitive resin composition preferably has a dielectric constant (e) of, for example, 3.0 or less and a dielectric loss tangent (tan δ) of, for example, 0.01 or less. Since the cured product having a low dielectric constant and a low dielectric loss tangent has good electrical properties when used in a high frequency range, it can be used in an electronic component, a semiconductor device, or others used in a high frequency range. Also, the reaction of the photosensitive resin composition in response to irradiation with active energy rays (for example, UV rays) is unlikely to proceed when the irradiation amount is not more than a certain amount. When the irradiation amount exceeds a certain amount, the reaction rapidly proceeds, the photosensitive resin composition is sufficiently cured, and a cured product having restrained film loss after development is obtained. Therefore, the photosensitive resin composition can be suitably used as a material for forming a rewiring layer (for example, a material for insulating layers). The photosensitive resin composition can be suitably used as a material for forming a wiring structure body which contains a rewiring layer.

The photosensitive resin composition can also be used as an interlayer adhesive film between multilayer wirings of a wiring structure body. Also, the photosensitive resin composition can be used for bonding or sealing components constituting a semiconductor device, a camera module, or an image sensor module.

An embodiment of the present disclosure can provide a photosensitive resin composition, a cured product thereof, a wiring structure body including the cured product, an electronic component including the cured product, a semiconductor device including the cured product, and a camera module including the cured product. Examples of the electronic component include those containing a wiring structure body used in electronic equipment such as a cellular phone, a smartphone, a notebook computer, and a tablet terminal. Examples of the semiconductor device include a memory device such as a D-RAM (Dynamic Random Access Memory), a processor device such as a CPU (Central Processing Unit) or a GPU (Graphics Processing Unit), a light-emitting element such as an LED (Light Emitting Diode), and a driver IC used in an LCD (Liquid Crystal Display) or others.

### Production Method of Cured Product

An example of the method of producing a cured product with the photosensitive resin composition will be described. The production method of a cured product can include a coating process of an object with the photosensitive resin composition, a preheating treatment (soft bake) process, an irradiation process with active energy rays, and a development process. An object to be coated with the photosensitive resin composition may be surface-treated before coated with the photosensitive resin composition. The production method of a cured product may include a surface treatment process of an object.

### Surface Treatment Process of Object

An example of the object is a semiconductor wafer. The semiconductor wafer can be subjected to surface activation treatment. An example of the surface activation treatment is plasma activation treatment. The surface treatment of an object can enhance bonding strength between the photosensitive resin composition and the object.

### Coating Process

The photosensitive resin composition is preferably applied on the surface-treated object. Examples of an apparatus for applying the photosensitive resin composition include a screen printer, a dispenser, and a spin coater (for example, Headway Spinner (manufactured by Headway Research, Inc.) or WS-650-8B (manufactured by Laurell)). In the coating process, the photosensitive resin composition is preferably applied such that a uniform thin film is formed on the surface of the object.

### Preheating Treatment (Soft Bake)

The photosensitive resin composition applied on the object may be subjected to preheating treatment (soft bake) before irradiated with active energy rays. The temperature of the preheating treatment may be 80° C. or higher and lower than 150° C., or 100° C. to 140° C. The preheating treatment can be performed using a hot plate or a convection oven (hot air circulation-type oven). The time of the heat treatment is 1 to 10 minutes and preferably 5 to 10 minutes.

### Irradiation Process

After the preheating treatment performed as necessary, the photosensitive resin composition applied on the object is preferably irradiated with active energy rays to obtain a cured product. A patterned cured product may be formed by photolithography with a photo mask. Examples of the active energy rays include UV rays of 10 nm to 380 nm and visible rays of 380 nm to 760 nm. The wavelength of the active energy rays for curing the photosensitive resin composition is preferably 10 nm to 600 nm, more preferably 100 nm to 500 nm, further preferably 250 nm to 450 nm, and particularly preferably 300 nm to 400 nm. The atmospheric temperature during irradiation with active energy rays may be 0° C. to 100° C., 10° C. to 50° C., or 15° C. to 35° C. The time of irradiation with active energy rays differs depending on, for example, the volume of an object to be irradiated, and usually 5 seconds to 60 minutes.

### Development Process

A patterned cured product is preferably obtained by removing the photo mask after irradiation with active energy rays and washing an uncured photosensitive resin composition with a developer or a solvent. The solvent may be used as a developer. Examples of the solvent used as a developer include an alcohol-based solvent, an ether-based solvent, a ketone-based solvent, an amide-based solvent, an ester-based solvent, and a hydrocarbon-based solvent. Examples of the alcohol-based solvent include a C₁ to C₁₈ monoalcohol-based solvent such as isopropanol, 4-methyl-2-pentanol, or n-hexanol and a C₂ to C₁₈ polyhydric alcohol-based solvent such as ethylene glycol. Examples of the ether-based solvent include a dialkyl ether-based solvent such as diethyl ether or dipropyl ether, a cyclic ether-based solvent such as tetrahydrofuran, and an aromatic-containing ether-based solvent such as diphenyl ether. Examples of the ketone-based solvent include a cyclic ketone-based solvent such as acetone, butanone, or methyl isobutyl ketone and a cyclic ketone-based solvent such as cyclopentanone or cyclohexanone. Examples of the amide-based solvent include a cyclic amide-based solvent such as N,N′-dimethylimidazolidinone or N-methylpyrrolidone and a cyclic amide-based solvent such as N-methylformamide or N,N-dimethylformamide.

Examples of the ester-based solvent include a monocarboxylic acid ester-based solvent such as n-butyl acetate, a polyhydric alcohol partial ether acetate-based solvent such as diethylene glycol mono-n-butyl ether acetate or propylene glycol monomethyl ether acetate, and a lactone-based solvent such as γ-butyrolactone. Examples of the hydrocarbon-based solvent include an aliphatic hydrocarbon-based solvent such as n-hexane and an aromatic hydrocarbon-based solvent such as benzene or toluene. The solvent used as a developer is preferably a ketone-based solvent or an ester-based solvent. The solvent used as a developer is preferably cyclopentanone, cyclohexanone, or propylene glycol monomethyl ether acetate. After washing with the solvent, washing (rinsing) treatment with deionized water or others may be performed.

An embodiment of the present disclosure can provide a photosensitive resin composition, a cured product thereof, a wiring structure body including the cured product, an electronic component including the cured product, a semiconductor device including the cured product, and a camera module including the cured product.

### EXAMPLES

Hereinafter, an embodiment of the present disclosure will be specifically described by examples. The technology of the present disclosure is not limited to these examples. In Examples and Comparative Examples described below, numbers indicating the formulation ratios of components contained in the photosensitive resin composition are all expressed in parts by mass.

### Component (A): Modified Polyphenylene Ether (PPE) Resin

A-1: OPE 2st 1200 (a modified polyphenylene ether resin represented by formula (1) with a vinyl group at both terminals (a reaction product between 2,2′,3,3′,5,5′-hexamethylbiphenyl-4,4′-diol·2,6-dimethylphenol condensate and chloromethylstyrene, number average molecular weight: 1160)) (manufactured by Mitsubishi Gas Chemical Company Inc.)

### Component (B): Silsesquioxane Compound

B-1: Acrylo POSS Cage Mixture MA0736 (containing a compound represented by formula (3) having a cage-type silsesquioxane structure with eight acryloyloxypropoxy groups) (manufactured by Hybrid Plastic Inc.)

### Component (C): Photopolymerization Initiator

C-1: Irgacure OXE-02 (oxime ester-based photopolymerization initiator, manufactured by BASF)

C-2: Omnirad 819 (former Irgacure 819) (acyl phosphine oxide-based photopolymerization initiator, manufactured by IGM Resins B.V)

C-3: Omnird 369 (former Irgacure 369) (alkylphenone-based photopolymerization initiator, manufactured by 1GM Resins B.V.)

### Component (E): Bifunctional Acrylic Resin

E-1: SR9003B (propoxylated (2) neopentyl glycol diacrylate, manufactured by Sartomer Chemical Co.)

E-2: SR601 (ethoxylated (4) bisphenol A diacrylate, manufactured by Sartomer Chemical Co.)

### Examples 1 to 12 and Comparative Examples 1 to 4

Component (A), component (B), component (C), and, as necessary, component (D) were mixed at the ratios indicated in Tables 1 to 3 using a planetary centrifugal mixer (ARE-310, Thinky Corporation) thereby to produce photosensitive resin compositions of Examples and Comparative Examples.

### Production of Cured Product: Coating Process and Preheating Treatment Process

With each of the photosensitive resin compositions according to Examples and Comparative Examples, a cured product constituting a wiring pattern was produced by photolithography.

First, a silicon wafer with a diameter of 150 mm was prepared as an object.

The silicon wafer was spin-coated with each of the photosensitive resin compositions according to Examples and Comparative Examples using a spin coater (WS-650-8B, manufactured by Laurell). In the spin coating, the spin coater operated at 500 rpm for 12 seconds and subsequently at 1500 rpm for 20 seconds. Accordingly, the surface of the silicon wafer was spin-coated with the photosensitive resin composition to form a thin film.

Next, the silicon wafer having the thin film of the photosensitive resin composition was subjected to preheating treatment (soft bake) under the ambient atmosphere at 120° C. for 5 minutes to dry the photosensitive resin composition by heating. Accordingly, there was obtained a sample including the thin film of the photosensitive resin composition having a film thickness of 13 μm. The film thickness of the thin film of the photosensitive resin composition was measured by a stylus-type profiling system (DektakXT, manufactured by BRUKER Co.).

This sample was subjected to the following photolithography test, and a cured product cured by photolithography was obtained.

### Production of Cured Product: Irradiation Process

### Photolithography Test

On the surface of the thin film containing the photosensitive resin composition of the sample, a mask (1951 USAF resolution test chart, thickness: 1.5 mm, manufactured by Advance Reproductions) was placed. With the mask in intimate contact with the surface of the thin film, the sample was irradiated with UV rays under the following conditions. On the mask, multiple rectangular regions (450 μm×450 μm) are disposed. On each of these regions, two wiring patterns, each having three straight lines aligned in parallel, are formed. These two wiring patterns each having three straight lines aligned in parallel are disposed in directions orthogonal to each other. Of these regions, one wiring pattern has three straight lines with an b/S of 2 μm/2 μm.

### UV Irradiation Conditions

UV irradiation device: Bluewave (registered trademark) QX4 (manufactured by DYMAX)

(Attached with, as a light source, LED Heads RediCure (registered trademark) (manufactured by DYMAX))

Active energy rays: UV rays: wavelength 365 nm

Irradiation amount: 135 mJ/cm²

Irradiation time: 10 seconds

Distance between mask and light source: 45 μm

### Production of Cured Product: Development Process

After completion of UV irradiation, the mask was removed from the sample. Using propylene glycol monomethyl ether acetate (2PGMEA) as a developer, development treatment was performed in which an uncured photosensitive resin composition was washed away from the sample. In the development treatment, two types of development treatments, one 50 seconds development treatment and two 50 seconds development treatments, were performed. In the former development treatment, the sample was immersed for 50 seconds in the developer in an amount that allows the entire sample to be immersed. In the latter development treatment, the sample was immersed in the developer for 50 seconds, removed from the developer, air-dried in the ambient atmosphere, and thereafter immersed in the developer for 50 seconds again. After the development treatment, the sample was removed from the developer and air-dried in the ambient atmosphere. Accordingly, a cured product having a wiring pattern structure was obtained.

### Evaluation Method

The thin film and the cured product obtained by the previously-described production method of a cured product were evaluated as follows. The evaluation result is illustrated in tables.

### Film Formation Properties (Optimum Filming)

The film thickness of the thin film formed by spin-coating a silicon wafer with each of the photosensitive resin compositions according to Examples and Comparative Examples was visually observed. Then, the film formation properties of each of the photosensitive resin compositions according to Examples and Comparative Examples was evaluated as follows.

Excellent: When a uniform thin film is formed on the entire surface of the silicon wafer.
Bad: When the surface of the silicon wafer has a portion in which a thin film is not formed.

### Patterning Properties

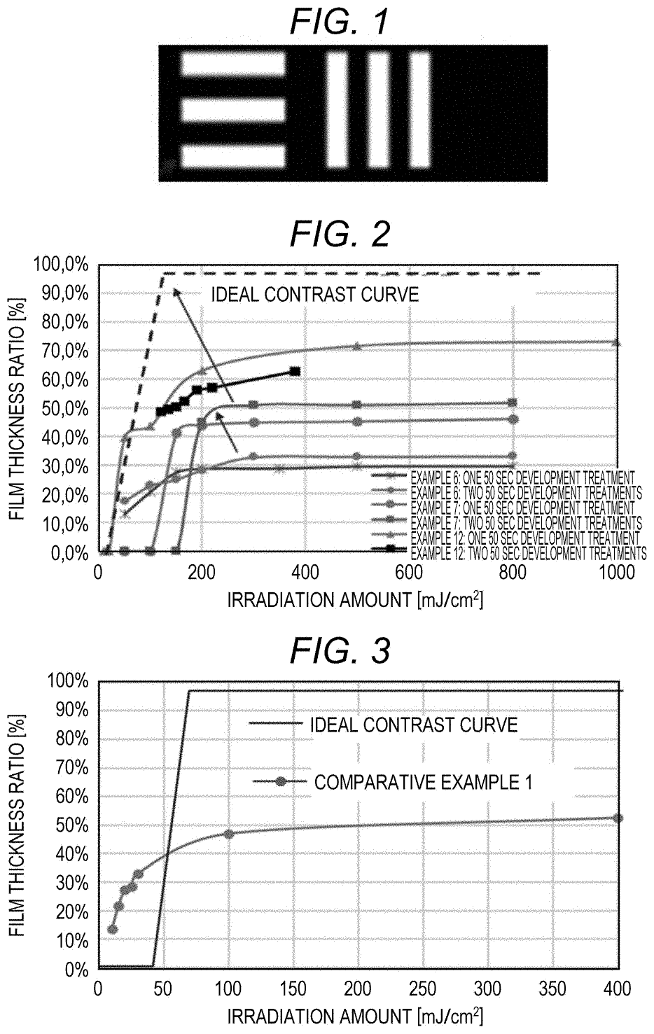

The cured product after the photolithography test was observed and photographed by a scanning electron microscope (SEM). On an SEM photograph obtained by this photographing, patterning properties were observed. FIG. 1 is an enlarged view illustrating an example of a three-line pattern having an L/S of 2 μm/2 μm. The patterning properties of the cured product according to each of Examples and Comparative Examples were evaluated as follows.

Excellent: When formation of a three-line pattern having an US of 2 μm/2 μm is observed in an SEM photograph.
Good: When it is observed in an SEM photograph that although a pattern having an US of not 2 μm/2 μm is included in three-line patterns, a three-line pattern is formed.
Bad: When it is observed in an SEM photograph that a three-line pattern is not formed, and a pattern having a crushed shape is formed.

### Contrast Curve

A cured product was obtained with the photosensitive resin composition of each of Examples and Comparative Examples by varying the irradiation amount (mJ/cm²) of UV rays for each sample in the photolithography test. For each irradiation amount, a film thickness ratio, which is a ratio of a film thickness of a cured product after UV irradiation relative to a film thickness of a thin film of the photosensitive resin composition before UV irradiation, was measured. The relationship between the irradiation amount and the film thickness ratio was plotted. The film thickness of the thin film of the photosensitive resin composition before UV irradiation is 13 μm as previously described. The film thickness of the cured product after UV irradiation was measured as follows. That is, the cross section of one line of the three-line pattern formed on the sample was observed and photographed by an SEM. From an SEM photograph obtained by this photographing, a thickness from the surface of the silicon wafer to the top of the pattern was derived, and this thickness was measured as a film thickness of the cured product. In the ideal contrast curve, the photosensitive resin composition does not react when the irradiation amount is not more than a certain amount, and the reaction rapidly proceeds when the irradiation amount exceeds a certain amount, so that the film thickness ratio sharply rises at the start relative to the irradiation amount. Also, in the ideal contrast curve, the film thickness ratio is thereafter constant even when the irradiation amount further increases, demonstrating that the reaction has reached saturation. A contrast curve indicating the relationship between the irradiation amount and the film thickness ratio when the photosensitive resin composition of each of Examples and Comparative Examples was cured was evaluated as follows.

Excellent: When in a contrast curve indicating the relationship between the irradiation amount and the film thickness ratio, the film thickness ratio remains closer to 0 when the irradiation amount is 30 mJ/cm² or less, and the film thickness ratio increases by 40% or more while the irradiation amount exceeds 30 mJ/cm² and increases from 50 mJ/cm² to 100 mJ/cm².
Good: When in a contrast curve indicating the relationship between the irradiation amount and the film thickness ratio, the film thickness ratio is 1 to 10% when the irradiation amount is 30 mJ/cm² or less and increases by 40% or more while the irradiation amount exceeds 30 mJ/cm² and increases from 50 mJ/cm² to 100 mJ/cm².
Bad: When in a contrast curve indicating the relationship between the irradiation amount and the film thickness ratio, the film thickness ratio exceeds 10% even when the irradiation amount is 30 mJ/cm² or less, and an increase in the film thickness ratio is less than 40% even when the irradiation amount exceeds 30 mJ/cm² and increases from 50 mJ/cm² to 100 mJ/cm².

### Dielectric Constant (ε) and Dielectric Loss Tangent (tan δ)

A measurement sample was prepared as follows.

The photosensitive resin composition was applied on a support body and subjected to preheating treatment (soft bake) under the ambient atmosphere at 120° C. for 5 minutes to dry the photosensitive resin composition by heating. Accordingly, there was obtained a thin film of the photosensitive resin composition having a film thickness of 13 μm.

The dielectric constant (e) and the dielectric loss tangent (tan δ) of the measurement sample were measured by a split post dielectric resonator (SPDR) at a dielectric resonance frequency of 10 GHz. The dielectric constant (ε) is preferably 1.5 to 3.3 and more preferably 1.5 to 2.8. The dielectric loss tangent (tan δ) is preferably 0.001 to 0.010.

TABLE 1

| | | | | | | | | Comparative | Comparative |
|---|---|---|---|---|---|---|---|---|---|
| | | | Example 1 | Example 2 | Example 3 | Example 4 | Example 5 | Example 1 | Example 2 |
| Component (A) | A-1 | OPE 2st 1200 | 100.00 | 100.00 | 100.00 | 100.00 | 100.00 | 100.00 | — |
| Component (B) | B-1 | POSS MA0736 | 4.44 | 3.23 | 11.11 | 42.86 | 100.00 | — | 100.00 |
| Component (C) | C-1 | Irgacure OXE-02 | 7.50 | 7.50 | 7.50 | 7.50 | 7.50 | 7.50 | 7.50 |
| | C-2 | Omnird 369 | — | — | — | — | — | — | — |
| | C-3 | Omnird 819 | — | — | — | — | — | — | — |
| Component (D) | D-1 | SR9003B | — | — | — | — | — | — | — |
| | D-2 | SR601 | — | — | — | — | — | — | — |
| Total amount | | | 111.94 | 110.73 | 118.61 | 150.36 | 207.5 | 107.50 | 107.50 |
| A/A + B | | | 0.96 | 0.97 | 0.90 | 0.70 | 0.50 | — | — |
| D/B + D | | | — | — | — | — | — | — | — |
| Evaluation | Film formation | | Excellent | Excellent | Excellent | Excellent | Excellent | Excellent | Bad |
| | properties (filming) | | | | | | | | |
| | Patterning | | Excellent | Excellent | Excellent | Excellent | Excellent | Excellent | Bad |
| | properties | | | | | | | | |
| | Contrast curve | | Excellent | Excellent | Excellent | Excellent | Excellent | Bad | Bad |
| | High-frequency | Dielectric | 2.6 | 2.6 | 2.7 | 2.6 | 2.7 | 1.8 | 2.7 |
| | properties (10 GHz) | constant (ε) | | | | | | | |
| | | Dielectric | 0.001 | 0.001 | 0.001 | 0.002 | 0.005 | <0.001 | 0.012 |
| | | loss tangent | | | | | | | |
| | | (tanδ) | | | | | | | |

TABLE 2

| | | | Example 6 | Example 7 | Example 8 | Example 9 | Example 10 | Example 11 |
|---|---|---|---|---|---|---|---|---|
| Component (A) | A-1 | OPE 2st 1200 | 100.00 | 100.00 | 100.00 | 100.00 | 100.00 | 100.00 |
| Component (B) | B-1 | POSS MA0736 | 4.44 | 4.44 | 4.44 | 4.44 | 4.44 | 4.44 |
| Component (C) | C-1 | Irgacure OXE-02 | 1.82 | 3.68 | 11.22 | 14.67 | — | — |
| | C-2 | Omnird 369 | — | — | — | — | 7.50 | — |
| | C-3 | Omnird 819 | — | — | — | — | — | 7.50 |
| Component (D) | D-1 | SR9003B | — | — | — | — | — | — |
| | D-2 | SR601 | — | — | — | — | — | — |
| Total amount | | | 106.26 | 108.12 | 115.66 | 119.11 | 111.94 | 111.94 |
| A/A + B | | | 0.96 | 0.96 | 0.96 | 0.96 | 0.96 | 0.96 |
| D/B + D | | | — | — | — | — | — | — |
| Evaluation | Film formation | | Excellent | Excellent | Excellent | Excellent | Excellent | Excellent |
| | properties (filming) | | | | | | | |
| | Patterning | | Excellent | Excellent | Excellent | Good | Excellent | Excellent |
| | properties | | | | | | | |
| | Contrast curve | | Good | Good | Excellent | Excellent | Excellent | Excellent |
| | High-frequency | Dielectric | 2.7 | 2.6 | 2.6 | 2.6 | 2.6 | 2.6 |
| | properties (10 GHz) | constant (ε) | | | | | | |
| | | Dielectric | 0.004 | 0.002 | 0.002 | 0.002 | 0.001 | 0.001 |
| | | loss tangent | | | | | | |
| | | (tanδ) | | | | | | |

TABLE 3

| | | | | Comparative | Comparative |
|---|---|---|---|---|---|
| | | | Example 12 | Example 3 | Example 4 |
| Component (A) | A-1 | OPE 2st 1200 | 100.00 | 100.00 | 100.00 |
| Component (B) | B-1 | POSS MA0736 | 4.44 | 0.00 | 0.00 |
| Component (C) | C-1 | Irgacure OXE-02 | 7.50 | 7.50 | 7.50 |
| | C-2 | Omnird 369 | — | — | — |
| | C-3 | Omnird 819 | — | — | — |
| Component (D) | D-1 | SR9003B | 95.00 | 95.00 | — |
| | D-2 | SR601 | — | — | 95.00 |
| Total amount | | | 206.94 | 202.50 | 202.50 |
| A/A + B + D | | | 0.50 | 0.51 | 0.51 |
| D/B + D | | | 0.96 | 1.00 | 1.00 |
| Evaluation | Film formation properties (filming) | | Excellent | Excellent | Excellent |
| | Patterning properties | | Excellent | Excellent | Excellent |
| | Contrast curve | | Excellent | Bad | Bad |
| | High-frequency | Dielectric constant (∈) | 2.6 | 2.7 | 2.7 |
| | properties (10 GHz) | Dielectric loss tangent (tanδ) | 0.001 | 0.003 | 0.002 |

As illustrated in Tables 1 to 3, the photosensitive resin compositions of Examples 1 to 12 are excellent in film formation properties (filming) and patterning properties. Furthermore, the photosensitive resin compositions of Examples 1 to 12 were sufficiently cured by UV irradiation to obtain a cured product of which film loss after development is restrained. Also, the photosensitive resin compositions of Examples 1 to 12 had a low dielectric constant (e) and dielectric loss tangent (tan δ) and good electrical properties when used in a high frequency range. In the photosensitive resin compositions of Examples 1 to 12, a contrast curve indicating the relationship of the film thickness ratio relative to the irradiation amount was closer to the ideal contrast curve. That is, in these contrast curves, the reaction of the photosensitive resin composition was unlikely to proceed when the irradiation amount was not more than a certain amount, rapidly proceeded when the irradiation amount exceeded a certain amount so that the film thickness ratio sharply rose at the start, and the film thickness ratio thereafter became constant even when the irradiation amount further increased. Therefore, according to the photosensitive resin compositions of Examples 1 to 12, a miniaturized and accurate pattern having an US of 2 μm/2 μm or less could be formed by photolithography.

FIG. 2 is a graph indicating contrast curves for the cured products obtained with the photosensitive resin compositions of Examples 6, 7, and 12. These contrast curves indicate the relationship of the film thickness ratio relative to the irradiation amount when one 50 seconds development treatment and two 50 seconds development treatments were performed. It could be confirmed that even when one 50 seconds development treatment and two 50 seconds development treatments were performed, the photosensitive resin composition of the same example exhibited contrast curves having a similar trend. As illustrated in FIG. 2, the photosensitive resin composition of Example 6 exhibited a contrast curve closer to the ideal contrast curve. That is, in the contrast curves of Example 6, the reaction of the photosensitive resin composition was unlikely to proceed when the irradiation amount was not more than a certain amount, and proceeded when the irradiation amount exceeded a certain amount, and the film thickness ratio thereafter became constant even when the irradiation amount further increased. The photosensitive resin composition of Example 7 exhibited a contrast curve that is further closer to the ideal contrast curve. That is, in the contrast curves of Example 7, the reaction of the photosensitive resin composition was unlikely to proceed when the irradiation amount was not more than a certain amount, and rapidly proceeded when the irradiation amount exceeded a certain amount, so that the film thickness ratio sharply rose at the start. Thereafter, the film thickness ratio became constant even when the irradiation amount further increased. The photosensitive resin composition of Example 12, which includes the bifunctional acrylic resin of component (D), exhibited a contrast curve closer to the ideal contrast curve by UV irradiation. That is, in the contrast curves of Examples 12, unreacted component (A) and component (D) reacted even after curing rapidly proceeded, and the film thickness ratio slowly increased.

As illustrated in Tables 1 and 3, the photosensitive resin compositions of Comparative Examples 1 to 4 did not exhibit a contrast curve closer to the ideal contrast curve. The photosensitive resin composition of Comparative Example 2, which does not include the PPE of component (A), was bad in film formation properties and patterning properties. The photosensitive resin compositions of Comparative Examples 3 and 4 include the bifunctional acrylic resin of component (D) but do not include the silsesquioxane compound of component (B). Therefore, the reaction did not rapidly proceed even when the irradiation amount exceeded a certain amount, and a contrast curve closer to the ideal contrast curve was not obtained.

As illustrated in FIG. 3, the photosensitive resin composition of Comparative Example 1 does not include the silsesquioxane compound of component (B). Therefore, curing proceeds even when the irradiation amount is 30 mJ/cm² or less, and the film thickness ratio increases. Also, even when the irradiation amount exceeded 30 mJ/cm² and increased from 50 mJ/cm² to 100 mJ/cm², the reaction did not so rapidly proceed, and an increase in the film thickness ratio was less than 30%. Therefore, a large irradiation amount is needed until the film thickness ratio reaches constant. In this manner, the photosensitive resin composition of Comparative Example 1 did not exhibit a contrast curve closer to the ideal contrast curve.

### INDUSTRIAL APPLICABILITY

The photosensitive resin composition according to an aspect of the present disclosure does not require high-temperature heat treatment and can be used as an insulating material for wiring. This photosensitive resin composition can be used in, for example, an interlayer adhesive film and an insulating layer material for forming a rewiring layer, of a wiring structure body. Furthermore, the photosensitive resin composition according to an aspect of the present disclosure can be used for bonding or sealing components constituting an electronic component, a semiconductor device, a camera module, or an image sensor module.

1. A photosensitive resin composition comprising components (A) to (C) below:
(A) a modified polyphenylene ether resin represented by formula (1) below 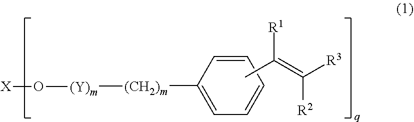
[wherein R¹ to R³ each independently represent a hydrogen atom, an alkyl group, an alkenyl group, or an alkynyl group,
X represents a q-valent unsubstituted or substituted aromatic hydrocarbon group,
Y represents an unsubstituted or substituted phenol repeating unit represented by formula (2) below 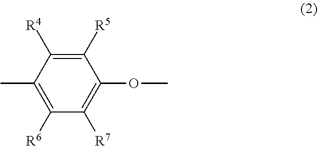
[wherein R⁴ to R⁷ each independently represent a hydrogen atom, an alkyl group, an alkenyl group, an alkynyl group, or an alkenylcarbonyl group],
m represents an integer of 1 to 100,
n represents an integer of 1 to 6, and
q represents an integer of 1 to 4];
(B) a compound represented by formula (3) below 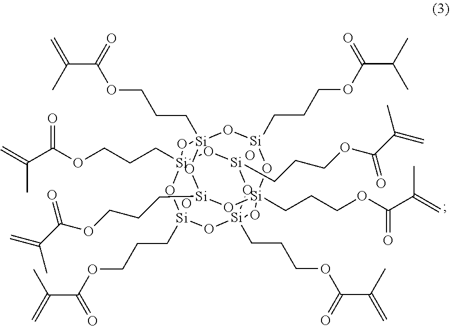 [SMILES: C=C(C)C(=O)OCCC[Si]12O[Si]3(CCCOC(=O)C(=C)C)O[Si]4(CCCOC(=O)C(=C)C)O[Si](CCCOC(=O)C(=C)C)(O1)O[Si]1(CCCOC(=O)C(=C)C)O[Si](CCCOC(=O)C(=C)C)(O2)O[Si](CCCOC(=O)C(=C)C)(O3)O[Si](CCCOC(=O)C(C)C)(O4)O1]
and
(C) a photopolymerization initiator.

2. The photosensitive resin composition according to claim 1, further comprising
(D) a bifunctional acrylic resin represented by formula (4) below 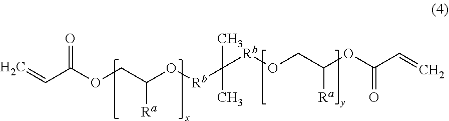
[wherein each R^{a} independently represents a hydrogen atom or a methyl group,
each R^{b} independently represents a divalent hydrocarbon group, and
x and y each independently represent an integer of 1 to 5].

3. The photosensitive resin composition according to claim 1,
wherein the component (C) is at least one selected from the group consisting of an acylphosphine oxide-based photopolymerization initiator, an oxime ester-based photopolymerization initiator, and an alkylphenone-based photopolymerization initiator.

4. The photosensitive resin composition according to claim 1,
wherein a mass ratio of the component (A) relative to a total amount of the component (A) and the component (B) is 0.10 to 0.99.

5. The photosensitive resin composition according to claim 1,
wherein a content of the component (C), relative to 100% by mass of the photosensitive resin composition, is 1.0 to 20.0% by mass.

6. The photosensitive resin composition according to claim 2,
wherein a mass ratio of the component (D) relative to a total amount of the component (B) and the component (D) is 0.01 to 0.99.

7. The photosensitive resin composition according to claim 1, further comprising
(E) a crystallizable or amorphous thermoplastic resin (excluding the bifunctional acrylic resin).

8. The photosensitive resin composition according to claim 7,
wherein the component (E) is at least one selected from the group consisting of a liquid crystal polymer, polyethylene, polypropylene, polyacetal, polyethylene terephthalate, polybutylene terephthalate, polyphenylene sulfide, polyether ketone, polytetrafluoroethylene, polyvinyl chloride, polystyrene, polymethyl methacrylate, acrylonitrile-butadiene-styrene, polycarbonate, polyether sulfone, polyether imide, and polyamide imide.

9. The photosensitive resin composition according to claim 1,
which is used for forming a wiring structure body containing a rewiring layer.

10. A cured product obtained by curing the photosensitive resin composition according to claim 1.

11. A wiring structure body comprising the cured product according to claim 10.

12. An electronic component comprising the cured product according to claim 10.

13. A semiconductor device comprising the cured product according to claim 10.

14. A camera module comprising the cured product according to claim 10.
